(19) United States
(12) Patent Application Publication
(10) Pub. No.: US 2011/0182442 A1
(43) Pub. Date: Jul. 28, 2011

(54) COMBINATION LINE OR MICROPHONE INPUT CIRCUITRY

(75) Inventors: BRADLEY SCOTT MCDONALD, AUSTIN, TX (US); BRIAN DAVID COX, ROUND ROCK, TX (US); BRIAN KEITH STRAUP, AUSTIN, TX (US)

(73) Assignee: OPEN LABS, INC., AUSTIN, TX (US)

(21) Appl. No.: 12/692,825

(22) Filed: Jan. 25, 2010

(51) Int. Cl. H03G 3/00

(52) U.S. Cl. 381/109; 381/123

(57) ABSTRACT

Combination line/microphone input circuitry is provided that adapts to receive either an audio line input or a microphone input via a single dual-purpose compound plug or input. More particularly, a combination line/microphone input circuit is provided to accept two different types of audio signals, being audio line signals and microphone signals, via a single dual-purpose plug or single input, such that the audio input circuitry is controlled or switched to accept either the audio line input or the audio microphone input signals, appropriately attenuate, filter and/or such input signals as necessary, then provide the resulting signal to other audio circuitry. Embodiments of the invention include additional circuitry that helps protect external line signal producing electronics from receiving incorrectly activated phantom microphone voltage.

### TECHNICAL FIELD

Embodiments of the present invention relate to circuitry that adapts to receive either an audio line input or a microphone input via a single dual-purpose compound plug or input. More particularly, embodiments of the present invention relate to audio input circuitry adapted to accept two different types of audio signals, being audio line signals and microphone signals, via a single dual-purpose plug or single input, such that the audio input circuitry is controlled or switched to accept either the audio line input or the audio microphone input signals, appropriately attenuate, filter and/or amplify such input signals as necessary, then provide the resulting signal to other audio circuitry. Embodiments of the invention include additional circuitry that helps protect external line signal producing electronics from receiving incorrectly activated phantom microphone voltage.

### BACKGROUND

On various types of audio electronic equipment, there are inputs or physical sockets for receiving various types of audio signals. For example, there may be a line input for receiving signals from the output of other audio equipment such as CD players, tape players, reel-to-reel players, record players, television audio output, video player audio output, sound mixing equipment and the like. On the same piece of equipment, there may also be a microphone input for receiving one or more different types of audio or acoustic signals from a microphone or musical instrument that incorporates an acoustic pick-up device. With separate sockets for each different kind of audio signal, the exterior surface of some audio equipment devices can become confusingly covered with many microphone sockets, line-in sockets and other connections. In some cases, next to each line plug and microphone plug, there may also be a gain control knob or slider to enable a user to adjust the gain of the signal that being input into the particular line input or microphone input socket. The gain control knobs for each input take up additional space on the equipment.

The audio equipment industry's interest in freeing-up exterior space or “real-estate” on audio equipment has, in some cases, lead to combining input sockets so that a single socket can accept multiple types of plugs and/or audio signals. For example, a single socket may be a combination of a line input socket and a microphone input socket thereby establishing a dual function input socket. Such a dual function input socket presently exists to allow both a quarter-inch plug, which is normally used for both line inputs and some microphone inputs, and an XLR style plug, which is also used for certain types of microphone inputs to connect to audio equipment. In many circumstances in the industry, a socket for a line connection or a microphone connection is referred to as a “jack”. The terms “dual function jack”, “combination jack”, “combo jack” or “dual function socket” may be used in the industry to describe a socket that is designed to receive either a XLR style microphone plug or a quarter-inch standard audio plug.

Some microphones require, what is referred to as, “phantom power” from the microphone jack. The phantom power is normally provided for a microphone at a voltage of about 48 volts DC. Phantom power is usually provided directly from the microphone jack that a microphone is plugged into. Phantom power is used by a microphone to power an amplifier, pre-amp or other device contained within the microphone. Generally, a phantom power switch or button is provided near the microphone jack on the audio equipment so that a user can switch on or off the 48-volt phantom power as necessary depending on the type of microphone that is plugged into the microphone jack. A gain control knob is generally also provided near a microphone jack to allow a user to adjust the microphone's signal gain. On some audio devices where a combo jack is used for both microphone and line inputs, the same gain control knob may be used by a user to adjust or set the gain of a line input signal that is plugged into the combo jack.

One common problem in the industry occurs when a combo jack is used for receiving either line or microphone input plugs. Sometimes when a line input is plugged into a combo jack, the user may have inadvertently left on or turned on the 48 volt DC phantom power. When the phantom power is on while a line input is plugged into a combo jack, the 48 volts is being provided to the line input plug that is plugged into the combo jack. At the other end of the line input plug cable one usually will find a line output jack on another piece of audio equipment. Most audio equipment is not designed to receive 48 volts DC at a line output. As such, audio equipment can be unnecessarily damaged when it receives 48 volts DC when phantom power is inadvertently left on when a line input plug is connected into a combo jack.

Referring now to FIG. 1, a prior art combo plug line/microphone jack and related circuitry block diagram is provided. The combo jack 100 is a combination jack, which combines the attributes of two types of jacks in a single socket. The combo socket 100 accepts both an XLR jack, which receives a three-prong plug from microphone devices and a quarter-inch jack, which receives a quarter-inch standard audio plug from either a microphone device or a line input from the line output of an audio device such as a CD player, mixing board, television, audio output or various other line outputs from audio devices. When an audio line input plug (not specifically shown) is connected to the combo jack 100 the line signal is connected from the combo jack 100 to the gain-attenuator stage 110. The gain-attenuation of the line signal is user adjusted via a variable resistor 112, which is also connected to the gain-attenuator stage circuitry 110. The output of the gain-attenuator stage provides an attenuated line signal to an amplifier pre-amp circuit 114 for additional filtering and amplification of the line signal prior to the line signal being output to other audio circuitry.

A microphone plug may be connected to the combo jack 100. The microphone plug may take one of two forms. The microphone plug, not specifically shown, may be a standard quarter-inch audio plug or a three-pronged XLR plug. Either plug type may be connected to the combo jack 100. If the microphone connected to the combo jack is a dynamic microphone that does not require phantom power, the phantom power switch 116 may be in the open or off position. If the connected microphone does not require phantom power, but the phantom power switch 116 is closed (on) and the phantom power voltage regulating circuit 118 is providing power, for example, 48 volts, to the combo jack, the microphone connected will not be damaged. If the microphone connected to the combo jack 100 is a condenser style microphone and requires phantom power, then a user must make sure that the phantom power switch 116 is closed so that the phantom power circuit 118 provides power to one of the combo jack's terminals for use by the connected microphone. Regardless of the type of microphone connected to the combo jack 100, the microphone's signal is provided to the combo jack 100 and in turn to the gain/attenuator stage 110. The variable resistor 112 can be user adjusted so that the gain of the microphone signal is adjusted as desired prior to being provided to the pre-amp circuit 114.

As discussed above, one problem with similar prior art combo jack line-microphone input socket circuitry is that if the phantom power switch 116 is closed (on) and the phantom power regulation circuit 118 is providing phantom power to the combo jack 100 while a line plug is connected to the combo jack 100, the audio device providing the line input to the combo jack could be damaged due to receipt of the 48 DC volt phantom power being provided at the combo jack 100.

Thus, what is needed is a combo jack and related circuitry that (a) accepts line input signals and microphone input signals audio signals; (b) provides user selectable phantom power to a connected microphone; (c) provides user adjustable gain for both line input signals and microphone input signals; and (d) provides a level of protection against delivering phantom power to line inputs.

### SUMMARY

In order to overcome the drawbacks of previous combination line/microphone circuitry embodiments of the invention provide a means for disabling phantom power from being connected to a combo jack input when operating in line mode.

In one embodiment of the invention, a combination line/microphone input circuit comprises a microcontroller that is adapted to perform various instructions. There is an input connection that receives a line input signal or a microphone input signal. The input connection may be in the form of a jack or combo jack having a plurality of contact connections. A user adjustable mechanism having its adjustment range divided into at least two portions, one portion being a microphone range and the other portion being a line mode range. The user adjustable mechanism may be a variable resistor, digital coder or adjustable encoder device. The user adjustable mechanism is monitored by the microcontroller during operation. Based on the microcontroller's interpretation of the user adjustable mechanism device's position, the microcontroller provides an appropriate gain instruction to a programmable preamp circuit. The programmable preamp circuit amplifies an input signal received at the input connection in accordance with the gain instruction provided by the microcontroller. Additionally, when the microcontroller determines that the user adjustable mechanism is within the line mode range, the microcontroller powers-down or disables a phantom power voltage output from being provided to a contact connection of the input connection. Conversely, when the microcontroller determines that the user adjustable mechanism is within the microphone mode resistance range, the microcontroller provides a signal to enable or power-up the phantom power voltage output only if a phantom power switch, as monitored by the microcontroller, is in an on position.

### BRIEF DESCRIPTION OF THE DRAWINGS

Other features and characteristics of embodiments of the invention as well as methods of operation and functions of related elements of structure and combination of parts and economics of manufacture will become apparent upon consideration of the following description and appended claims with reference to the accompanying drawings, all of which form a part of this specification wherein like reference numerals designate corresponding parts in the various Figures, and wherein:

FIG. 1 is a block diagram of a prior art combo plug line/microphone jack and related circuitry;

FIG. 2 depicts a drawing of an exemplary rheostat, variable resistor or digital device position knob comprising a microphone gain region and a line gain region in accordance with an embodiment of the invention;

FIG. 3 illustrates an exemplary block diagram/schematic of a combination line or microphone input circuit in accordance with an embodiment of the invention;

FIG. 4 is a flow chart of exemplary microcontroller control of exemplary circuitry when a user changes a phantom power setting; and

FIG. 5 is a flow chart of exemplary microcontroller control of exemplary circuitry when a user adjusts a gain setting from a microphone gain setting to a line gain setting.

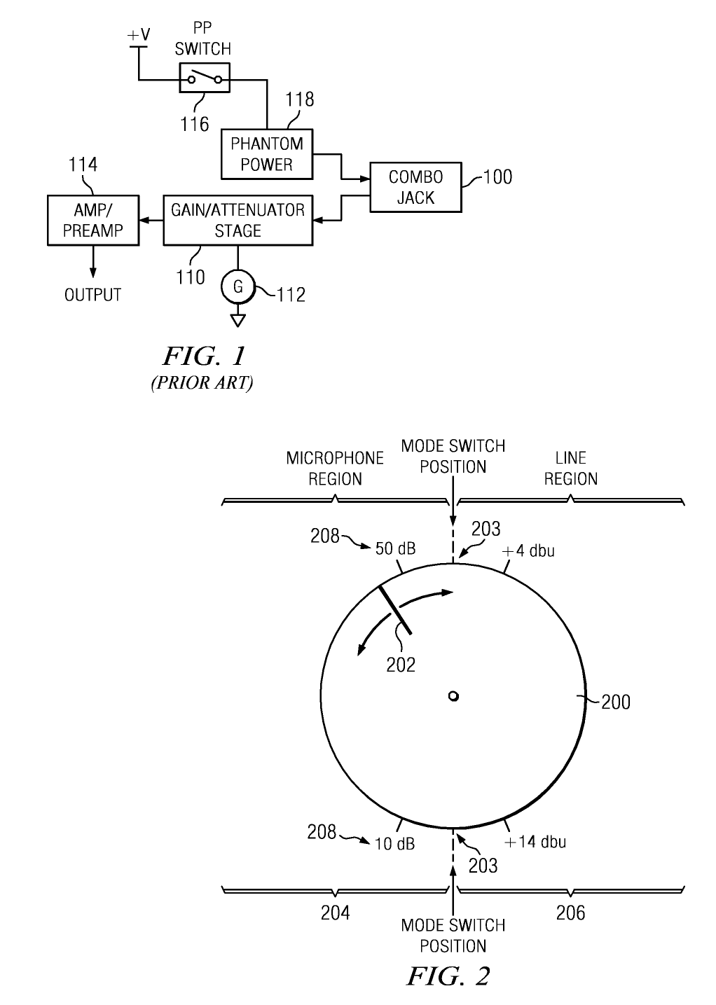

### DETAILED DESCRIPTION

Referring now to the drawings, wherein like reference numbers are used herein to designate like elements throughout, the various views and embodiments of exemplary combination line/microphone input circuitry are illustrated and described along with other possible embodiments and variations. The figures are not necessarily drawn to scale, and in some instances the drawings have been exaggerated and/or simplified in places for illustrative purposes only. One of ordinary skill in the art will appreciate the many possible applications and variations not specifically described herein based on the following description of the exemplary embodiments.

From a user's perspective, embodiments of the invention provide a user with an audio input that accepts microphone signals and line signals. Embodiments further provide a user with a gain adjustment that is divided into two gain regions. A first gain region is for adjusting the gain or amplification of a microphone input signal. A second gain region is for adjusting the gain or amplification of an input line signal. Further, regardless of whether the user has turned the phantom power on, embodiments disable or disconnect phantom power when the gain adjustment is in the gain region wherein the input line signal gain or amplification can be adjusted.

Referring now to FIG. 2, a front view of an exemplary user adjustable knob 200 and equipment face plate are shown. The adjustable knob is turned by a user to adjust the gain of a microphone or a line signal that is input into an exemplary device. The adjustment knob 200 is the human interface portion of a variable resistor, rheostat or digital position sensing device (not specifically shown). The adjustment knob 200 has an indicator 202 that is positioned by a user to point to a gain setting labeled on the equipment surface or faceplate about the knob 200. The area about the adjustment knob 200 is divided into two regions. One region about the adjustment knob 200 is the microphone region 204. The other region about the adjustment knob 200 that the indicator 202 can be positioned to point in is the line region 206. The microphone region 204 provides variable amplification settings ranging substantially continuously from about 0 dB to a predetermined maximum amount of amplification. In the embodiment shown in FIG. 2, the maximum amplification setting is about 68 dB in the microphone region 204, but in other exemplary embodiments, the maximum predetermined amplification is a design variant that can range from a few dB to 100 dB or more.

In the line region 206 of the adjustment knob range, there are two distinct gain settings. One line gain setting is +4 dBu and the other line gain setting is a +14 dBu setting. The setting is indicative of the amount of voltage the line gain input is set to accept. As will be explained, when the indicator 202 is positioned in the line region portion, the underlying exemplary circuitry that utilizes a gain stage attenuator circuit as well as an amplification circuit to produce an overall output gain of the input line signal of either +4 dBu gain or +14 dBu. The +4 dBu setting is a higher gain setting that is typically used for line outputs connected to consumer level recording audio equipment, while the +14 dBu setting is the gain setting that is typically used in professional studio recording set ups.

Exemplary embodiments may utilize a detented potentiometer or rheostat under the adjustment knob so that as a user turns the adjustment knob 200, the user will sense clicks, notches or spaced settings that are equally spaced about the rotational limits of the rheostat. In various embodiments, a user-adjustable mechanism such as a potentiometer, resistive slider, a digital position sensor or a shaft encoder could be used. A detented potentiometer may help the user select or reselect a user-selectable gain setting. The potentiometer or rheostat associated with the gain adjustment knob 200 may, in some embodiments, rotate smoothly when a user rotates or moves the adjustment knob 200 into a selected gain setting. It is a safeguard of embodiments that when the pointer 202 of the adjustment knob 200 is moved to point into the line region area 206, embodiments of the invention will disconnect or disallow phantom power from being provided to the combo jack regardless of whether phantom power is set to be on or off. This safeguard is important in order to decrease the likelihood of a line input plug being subjected to phantom power that may damage the equipment originating the line signal.

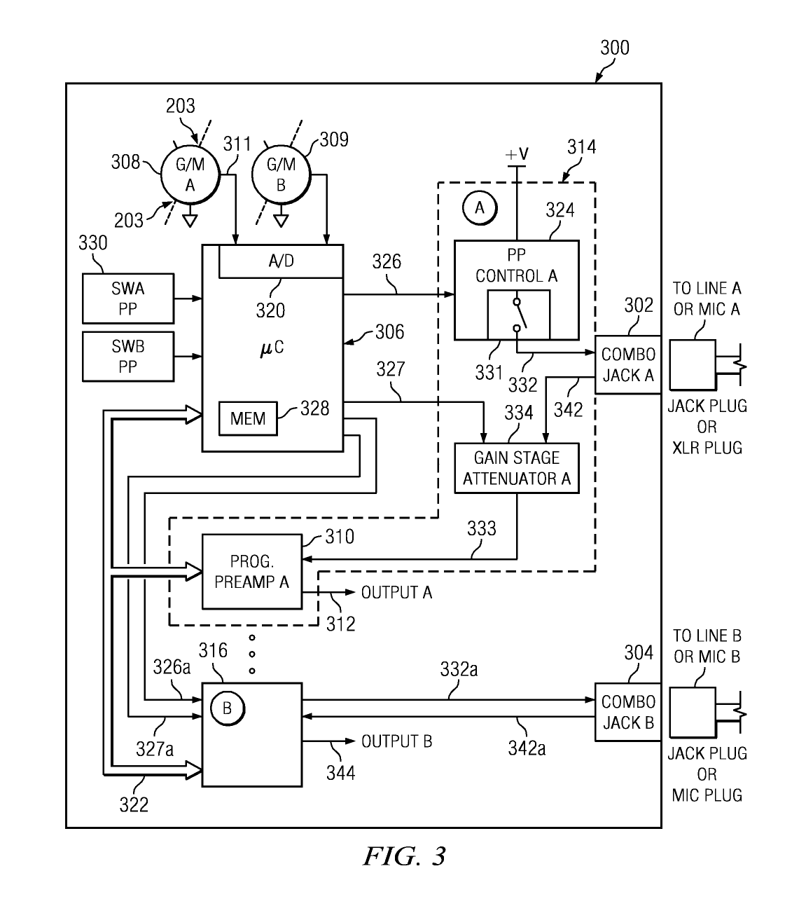

FIG. 3 depicts an exemplary block diagram of an exemplary combination line/microphone input circuit 300. The exemplary combination line/microphone input circuit 300 comprises two combo jacks, being combo jack A 302 and combo jack B 304. In additional embodiments, additional combo jacks may be included along with their associated circuitry. Each combo jack 302, 304 is an input connection that accepts either an XLR plug, which has three connection pins or contacts (not specifically shown) or a standard quarter-inch audio plug that has two or more connection pins or contacts (also not specifically shown). If the combo jack A 302 or combo jack B 304 is connected to receive a line input, then gain-mode knob A 308 or gain-mode knob B 309, respectively should be set by the user to have their associated indicators 202 pointing in the line region 206, When the respective gain-mode knobs 308, 309 are pointing or set to be in the line region 206, then embodiments of the invention 300 are set to receive a line inputs at both combo jack A 302 and combo jack B 304. Each line input signal has a line level or signal level, which is a term used to denote the strength of a line audio signal. A line audio signal is generally used in audio equipment to carry analog sound information between audio components such as CD and DVD players, TV's, audio amplifiers, mixing consoles and sometimes MP3 players.

A line level describes the line input's nominal signal level as a ratio. The line level is expressed in decibels against a standard reference voltage. Generally, there are two reference voltages that are commonly used, one being decibel volts (dBV) for consumer allocations, and decibels unloaded (dBu) for professional applications. The reference voltage for the decibel volt (0 dBV) is 1 V_{RMS}, which is the voltage required to produce 1 milliwatt (mW) of power across 1 kilohms (kΩ) load. The reference voltage for the decibel unloaded (0 dBu) is the voltage required to produce 1 mW of power across 600Ωs of load (approximately 0.7746 V_{RMS}).

The exemplary combo jack A 302 and combo jack B 304 and their respective related circuitry can also receive acoustic sound signals on one or more of the input connection contacts. The acoustic sound signals, such as voices or musical instrument signals, are often picked up using transducers (e.g., microphones or pickups). Microphones and transducers tend to produce weak electrical signals. The weak acoustic signals that are received by embodiments of the invention must be amplified to an acceptable line signal level so that they can be more easily manipulated by other electronic audio devices such as mixing consoles, special sound effect equipment and audio recording equipment. The input acoustic signals must be amplified by embodiments of the invention in accordance with the indicated amount of gain that the indicator 202 is pointing at in the microphone region 204. Such acoustic signals may be amplified by embodiments with a gain of from about 0 dB to a maximum predetermined gain amount ranging from about 60 dB to more than 100 dB. Such amplification is performed under microprocessor control based on the gain setting of the gain knob indicator 202 on the variable resistor or other variably adjustable mechanism 308, which via the microcontroller 306, control the programmable preamp device 310. The programmable preamp device 310 provides an output signal 312 indicated as output A in the circuit A portion 314 of FIG. 3. The gain setting indicated by the knob indicator 202 is represented to the microcontroller 306 as a voltage, a resistance, a digital or encoded output from the user-adjustable mechanism 308.

FIG. 3 depicts the microcontroller 306 that controls aspects of the circuit A portion 314, which receives either line or microphone input from an input connection in the form of a combo jack A 302. The microcontroller 306 further controls aspects of the circuit B portion 316, which receives input from combo jack B 304. Both circuit A portion 314 and circuit B portion 316 are substantially similar circuits. Thus to minimize repetition in the description of this embodiment 300, the focus herein will mainly be on the microcontroller 306 and circuit A portion 314, which combine to substantially complete one exemplary line/microphone input circuit embodiment. Additional combo jacks may be included in other embodiments of the invention. Such additional combo jacks will each have respective circuitry as depicted with, for example, combo jack A 302, but additional combo jacks may not require an additional microcontroller for each set of two combo jacks because much of the control circuitry can be shared or duplicated without needing an additional microcontroller.

Referring still to FIG. 3, the gain-mode A user-adjustable mechanism 308 is a type of user adjustable device such as a rheostat or potentiometer, or a type of user adjustable digital or encoded output device that is associated with the gain knob 200 shown in FIG. 2. The gain knob 200 of FIG. 2 could be replaced with a slider potentiometer, digital potentiometer or other types of user adjustable mechanisms or interfaces. The microcontroller electrically monitors the resistance, digital or encoded output of the adjustable mechanism 308. In some embodiments, the microcontroller 306 via an analog/digital converter circuit 320 reads a voltage 311 associated with the setting of the gain-mode mechanism 308 to determine whether the gain-mode knob's setting is within the microphone region 204 or the line region 206 (also may be referred to as the microphone mode gain range 204 or the line mode gain range). The setting of the gain-mode knob 308 further provides and indication of whether the phantom power control circuit should be enabled and/or connected to the combo jack A 302.

Assuming, for example, that the gain-mode A adjustable mechanism 308 is set at a setting that corresponds to a resistance within in the line region 206, then a voltage 311 associated with the resistance setting is produced by the gain-mode mechanism 308 that is read by the A/D converter 320. The A/D converter produces a digital value that represents the voltage 311 being sensed. The digital value is provided to the microcontroller 306. The digital value of the voltage 311 is used by the microcontroller to determine two things. First, the microcontroller can determine what mode, microphone mode or line mode, the exemplary embodiment is to set to operate within depending on what region or resistance range, the microphone region 204 or the line region 206, the gain-mode user adjustable resistance device or mechanism is set. Second, the microcontroller, with use of an associated gain-mode resistance digital value, provided by the A/D converter 320, can to look up the user-set gain setting in a look-up table stored in the memory 328. The microcontroller 306 may then send or communicate gain setting instructions to the programmable preamp 310 at via bus 322. Such gain setting instructions may include line mode gain setting instructions, microphone mode gain setting instructions and zero or minimum gain setting instructions. The memory 328 may be included as an integral part of the microcontroller 306 or may be separate, but in electrical communication with the microcontroller 306.

In other embodiments, a user adjustable digital potentiometer, a shaft encoder or digital position sensor may be used for the gain-mode mechanism 308. A digital position sensor produces a binary or digital output that is dependant on the position of user adjustable knob, slider or touch sensitive interface. If a digital position sensor is used in an embodiment of the invention, than an A/D converter 320, onboard or external to the microcontroller, may not be necessary in the circuit. Embodiments that use a shaft encoder or other type of encoder for the gain mode mechanism may operate similarly.

Furthermore, based on the mode determination (microphone mode or line mode), the microcontroller determines whether or not to connect or allow power from the phantom power circuit 324 to be provided to the combo jack A 302 input connection. The microcontroller 306 provides phantom power on and phantom power off signals via phantom power signal line 326 to the phantom power control circuit 324. If the microcontroller 306 determines that the embodiment is to operate in microphone mode, then the microcontroller may send a phantom power on signal 326 to the phantom power control circuit 324. The phantom power control circuit, in some embodiments, will respond to a phantom power on signal by enabling the phantom power voltage regulation circuit (not specifically shown) within or associated with the phantom power control circuit 324. In additional embodiments, the phantom power control circuit will also respond to the phantom power on signal by electrically closing or effectively enabling a connection 331 between a phantom power voltage output and a contact pin of the input connection or combo jack A 302. The closing of a connection may be performed, for example, by a relay device, while the effective enablement of a connection may be accomplished by a basic transistor switch circuit. Exemplary switching or relay circuits are represented by a relay 331.

The memory 328 may be onboard or external to the microcontroller 306. The memory 328 may store a plurality of instructions that are configured to cause the microcontroller 306 to perform various functions including, to provide, monitor and receive instructions or signals communicated to or from the adjustable mechanism 308, the programmable preamp 310, the phantom power switch 330, the phantom power control circuit 324, and the memory 328. The monitoring, providing and receiving of signals are related to the control of the operation of an exemplary embodiment. The memory 328 may be in the form of flash memory or EEPROM memory or another suitable type of non-volatile and potentially re-programmable memory. Embodiments of the invention may use a microcontroller 306 that is a PSOC microcontroller device made by Cypress Semiconductor Corporation or any reasonably suitable or similar microcontroller made by the same or another manufacturer. An exemplary microcontroller may be an 8-bit microcontroller, but will certainly operate using other size microcontrollers. One reason, but not a limiting reason, for selecting a PSOC microcontroller to incorporate into an embodiment is that the PSOC microcontroller includes an on board analog/digital conversion circuit. Regardless, such analog/digital conversion could be provided via a circuit that is peripheral to the microcontroller 306 or contained on another manufacturer's microcontroller family such as the 8051 family of microcontrollers now made by a large variety of manufacturers.

When the user adjustable mechanism 308 is positioned in the microphone range 204, the A/D converter 320 provides a digital indication of the position to the microcontroller 306. The microcontroller will also sense the switch position of the phantom power switch A 330. If the phantom power switch A 330 is switched to an off position, the microcontroller 306 will provide a phantom power off signal via phantom power signal line 326 to the phantom power control circuit A 324 instructing the phantom power control A 324 to disabled and/or to not connect the phantom power voltage regulator output to a connection contact of the combo jack A 302 via phantom power line 332. Conversely, if the phantom power switch A 330 is read or monitored to be in the on position by the microcontroller 306, then the microcontroller 306 will provide a phantom power on signal to the phantom power control circuit A 324 via the phantom power signal line 326 that indicates that the phantom power control circuit A 324 should enable or power-up a phantom power voltage regulator circuit so as to produce a phantom power output voltage and, in some embodiments, should electrically connect or allow the phantom power output voltage to be provided at a contact of the combo jack A 302 via phantom power line 332. Furthermore, the microcontroller 306 determines from the mechanism 308, via the A/D converter 320, the user selected gain. The microcontroller will signal or communicate with the programmable preamp 310 via the bus 322 and provide a gain instruction to adjust the amplification circuit within the programmable preamp 310 to produce an overall signal gain between the input connection line 342 and the output A 312 as selected by the user. In some embodiments of the invention, the programmable preamp 310 may be a digitally controlled microphone preamplifier that is the same as or somewhat similar to a Burr-Brown digitally controlled microphone preamplifier part no. PGA2500. Other comparable programmable preamps may be used successfully in embodiments of the invention.

If a user determines that they require a higher or lower amplification of the input microphone signal at output 312 from the programmable preamp 310, the user may adjust the gain-mode mechanism 308 by moving the pointing position of the indicator 202 within the microphone mode resistance range 204. Such an adjustment is monitored by the microcontroller via the A/D converter 320. The A/D converter 320 provides a new or changed digital representation or indication of the received voltage or indication 311 to the microcontroller 306, which compares the digital representation to a lookup table (not specifically shown) found in the memory 328. Based on the lookup table number, an appropriate preamp gain instruction is sent by the microcontroller 306, via the data bus 322, to the digitally programmable preamp 310 to change the amount of gain that is to be applied to an input signal received at the combo jack A 302. The input signal received at combo jack A 302 may be provided to the digitally programmable preamp 310 through, in some embodiments, a gain stage attenuator 334. In such an embodiment, where an input acoustic microphone signal is being received at the combo jack A 302, the gain stage attenuator 334 may simply allow the acoustic microphone signal to travel through with either no gain or a unity gain and minimal attenuation. The received acoustic microphone signal exits the gain stage attenuator 334 and proceeds, via a signal connection 333, to an input of the digitally programmable preamp 310. When the acoustic signal is received by the digitally programmable preamp 310, the preamp, in accordance with its gain setting instructions from the microcontroller 306, amplifies the microphone signal to the requested level and outputs the amplified microphone signal at output A 312 for use in other audio circuits.

When the gain-mode mechanism A 308, is positioned with the indicator 202 pointed into the line region or line mode resistance range 206, the A/D converter 320 senses the knob position or setting and provides a digital indication of the position to the microcontroller 306. The microcontroller 306 also senses the phantom power switch A′s 330 position. In some embodiments, regardless of the phantom switch A 330 being in an on or off position, the microcontroller will signal the phantom control circuit 324, via the phantom power signal line 326, to open the relay or transistor switch 331, such that the phantom power voltage output is disconnected from and made unavailable to the combo jack A 302. In other embodiments, when the microcontroller determines that the gain-mode mechanism A 308 is set in the line region 206, while the phantom power switch A 330 is in the on position, then regardless of the phantom power switch A 330 position, the microcontroller 306 will signal the phantom power voltage regulation portion of the phantom power control circuit 324 to power-down or to become disabled so as to not produce a phantom power voltage output. In yet other embodiments, the microcontroller may signal the phantom power voltage regulation circuit associated with the phantom power control circuit 324 to become both disabled and to disconnect from or open a phantom power output switch 331 such that phantom power cannot be received at a contact connection of combo jack A 302. In essence, embodiments of the invention aim to disable or disconnect phantom power from being provided to a connection of the combo jack 302 input connection when the mode-gain mechanism A 308 is positioned by a user to be in the line region 206 regardless of the phantom power switch A 330 being in an on or off position.

Furthermore, embodiments of the invention perform certain functions when power is on and a user adjusts the gain-mode mechanism A 308 such that the indicator 202 moves across a mode switch position 203. The mode switch position 203 is a location between or separating the microphone region 204 from the line region 206. When the indicator 202 is moved across a mode switch position 203 (a mode switch resistance position), the mode of an exemplary embodiment switches from operating in a microphone mode to operating in a line mode or vis-à-vis.

Furthermore, when the gain-mode mechanism A 308 indicator 202 is pointing in the line region 206, one of two distinct gain settings, +4 dBu or +14 dBu, are determined by the microcontroller 306 via the digital position indication of the gain-mode mechanism 308 provided by the A/D converter 320 to the microcontroller 306. Thus, the line mode region/range 206 may be divided into at least two regions or ranges being a +4 dBu range and a +14 dBu range. More than two ranges can also be created for other line input voltage/gain settings. The microcontroller interprets, via the memory 328 look-up table, that when the user has set the gain-mode mechanism 308 to be anywhere within, for example, the +4 dBu resistive or digitally encoded gain range, then a +4 dBu gain setting instruction is communicated to the programmable preamp 310.

In general, when the indicator 202 is moved across or over a mode switch position 203, the microcontroller 306 interprets the occurrence and immediately sends an instruction, via bus 322, to the programmable preamp 310 to adjust its gain to one of a minimum gain, a zero gain or to provide a minimal or no output signal at output A 312. Substantially simultaneously or in near succession, the microcontroller also sends a signal to the phantom power control circuit A 324 to disable or enable, to turn on or off and/or to electrically connect or disconnect the phantom power voltage output from the combo jack A 302 depending on whether the indicator 202 was moved to make the gain-mode mechanism 308 indicate that the mode of operation should be changed to microphone mode or line mode. If a gain stage attenuator 334 is included in an embodiment, then an appropriate attenuation setting is set by the microcontroller 306 via the gain stage signal line 327.

The gain stage attenuator 334, when incorporated into an embodiment, operates in conjunction with the programmable preamp 310. In some embodiments, a line input or microphone signal may require attenuation and/or filtering prior to being provided to the programmable preamp 310. Attenuation or some filtering may be needed or desired to help enable the programmable preamp 310 provide a cleaner amplified signal at output A 312. For example, in some embodiments when operating in microphone mode, the received microphone signals may be passed through the gain stage attenuator 334 with minimal to no attenuation or filtering, but if operating in line mode, one or both of the +4 dBu and +14 dBu line gain settings may require some predetermined amount of attenuation of the line input signal at the gain stage attenuator 334 prior to delivering the signal to the programmable preamp 310 via connection line 333. The microcontroller 306 provides a pass/attenuate signal via connection 327 to the gain stage attenuator 334. If the pass/attenuate signal indicates that the gain stage attenuator 334 should pass the line input or microphone input signal without any attenuation, the gain stage attenuator 334 may set its gain to 1 and pass the signal with minimal to zero attenuation. In some embodiments wherein no input signal attenuation is needed, the line input signal or microphone signal may be switched via a relay or solid state switch to bypass any attenuation circuitry in the gain stage attenuator 334. The line input signal or microphone input signal will then be provided to the programmable preamp 310 via electrical connection 333.

If the pass/attenuate signal indicates that the gain stage attenuator 334 should attenuate the line input or microphone input signal, the gain stage attenuator 334 may set its gain to a gain setting indicated by a gain signal from the microprocessor and attenuate the line input signal or microphone input signal prior to passing the attenuated signal to the programmable preamp 310. In other embodiments, the gain stage attenuator 334 may have a fixed or preset attenuation such that the line input signal or microphone input signal are switched via a relay or solid state switch to pass through the attenuation circuitry of the gain stage attenuator 334 prior to being provided to the programmable preamp 310 via signal connection 333.

If an embodiment does not include a gain stage attenuator, then the input line signal or input microphone signal received at the combo jack A 302 may be connected substantially directly to a programmable preamp with perhaps, in some embodiments, a filter circuit and some static or overvoltage protection circuitry there between.

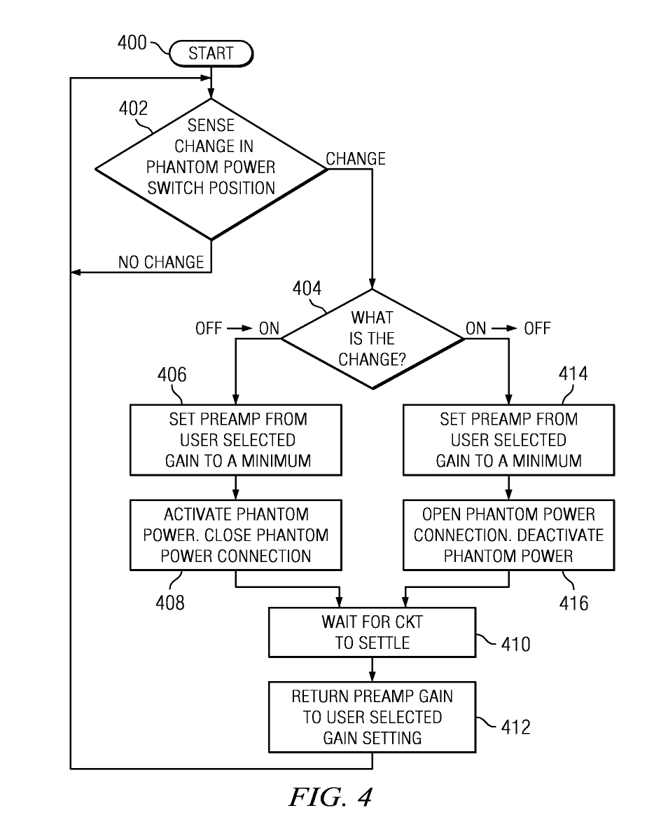

Referring now to FIGS. 2, 3 and 4, FIG. 4 depicts a flow chart of an exemplary method for an embodiment to respond to a user changing a microphone type. For example, if a user is changing from or disconnecting a dynamic microphone, which does not require phantom power, to using or connecting a condenser microphone, which does require phantom power from the combo jack A's 302 input connection then the following exemplary steps may occur. At step 400, the microcontroller 306 begins its process of monitoring, sending and receiving various signals, instructions inputs or outputs originating from circuitry associated with an exemplary embodiment. At step 402, the microprocessor monitors a change in the switch position of the phantom power switch A 330. Of course, if no change is monitored or sensed, then the firmware of the microprocessor continues to loop through its various monitoring and processing functions. Conversely, if the microcontroller 306 determines or senses that there has been a switch position change of the phantom power switch A 330, then at step 404 the microcontroller determines what about the phantom power switch position changed. In this initial example, assume a user changed from using a dynamic microphone, which does not require phantom power, to a condenser microphone, which does require phantom power. As such, the user will normally switch the phantom power switch position from an off position to an on position. At step 406, since the phantom power is being switched from an off position to an on position, which is sensed by the microcontroller 306, the microcontroller will send an instruction via the data bus 322 to the programmable preamp A 310 and, at least temporarily, override a user selected gain that a user selected via the gain-mode potentiometer/mechanism 308. During the temporary override, the microcontroller provides an instruction to the programmable preamp A 310 to change the preamp's gain to a minimum or zero gain value. At a minimum or zero gain value, the programmable preamp 310 will provide essentially no gain of the input signal or a zero or near zero signal output at output A 312. By minimizing the programmable preamp's gain, an overall audio system connected to the output A 312 may be protected from electrical spikes and amplifier noise occurring during component or component setting changes resulting in undesirable acoustic pops, clicks or booms, that may occur and be heard by a user via headphones, speakers or other sound system equipment.

At step 408, the microcontroller 306 signals the phantom power control circuit 324 via the phantom power control connection 326 with a phantom power on signal to turn on or to enable production of the regulated phantom power or 48 volts DC. Furthermore, a relay or transistor switch 331 may be signaled to close and essentially complete the circuit between a regulated voltage output of the phantom power control circuit and the connection 332 so that the phantom power voltage is provided to a contact connection of the combo jack A 302. At step 410, there may be a short waiting period of a few microseconds to a number of seconds to allow the exemplary phantom control power 324 and the programmable preamp circuitry output A 312 to settle. After the predefined waiting period, the microcontroller 306 reads an output of the A/D converter 320, which provides an indication of the gain-mode potentiometer/mechanism setting 308. The microcontroller 306 uses the knob setting indication from the A/D converter to look up a gain setting instruction from an appropriate lookup table entry found in the memory 328. The gain setting instruction is then sent by the microcontroller 306 to the programmable preamp 310. At this time, the programmable preamp adjusts its gain from 0 (or a minimal output level) to the designated gain setting associated with the monitored resistance or digital output of the gain-mode potentiometer/knob setting 308.

If a user was switching from a condenser microphone, which requires phantom power, to a dynamic microphone, which does not require phantom power, then at step 404 a change sensed by the microcontroller 306 of the phantom power switch A 330 would normally be due to a user switching the phantom power switch A 330 from an on position to an off position. At step 414, the microcontroller 306 sends a zero gain setting instruction via a data bus 322 to the programmable preamp 310 to change its gain to a minimum or zero output setting. The moving of the gain to a minimum or zero gain output setting ensures that the output A 312 is not providing a significant output while the phantom power control circuit is changing states.

At step 416, one or both of the following may occur. First, a phantom power connection via a relay switch or transistor switch 331 is opened disconnecting the regulated phantom power voltage output from the phantom power line 332 and the combo jack A 302. A second event that may occur in some embodiments at step 416 is the powering down or disabling of the phantom power regulated voltage circuit via the phantom power control circuit such that a phantom power regulated voltage output is not being produced. At step 410, the circuitry waits a microsecond or a few seconds (or some other predetermined amount of wait time) for the programmable preamp 310 and the phantom power control circuit A 324 to settle. The wait time may substantially eliminate a potential for unwanted noise on output A 312 of the preamp. Finally, at step 412, the programmable preamp gain is adjusted to the gain setting set by the user at the gain-mode potentiometer/knob 308, whose voltage is read by the A/D converter 320 and converted to a digital representation, which is used by the microcontroller 306 to look up in a look-up table for the appropriate gain setting instruction in the memory 328. The appropriate gain setting instruction is then passed to the programmable preamp 310 via the data bus 322 such that the programmable preamp 310 increases its gain to the user defined or user selected microphone gain setting.

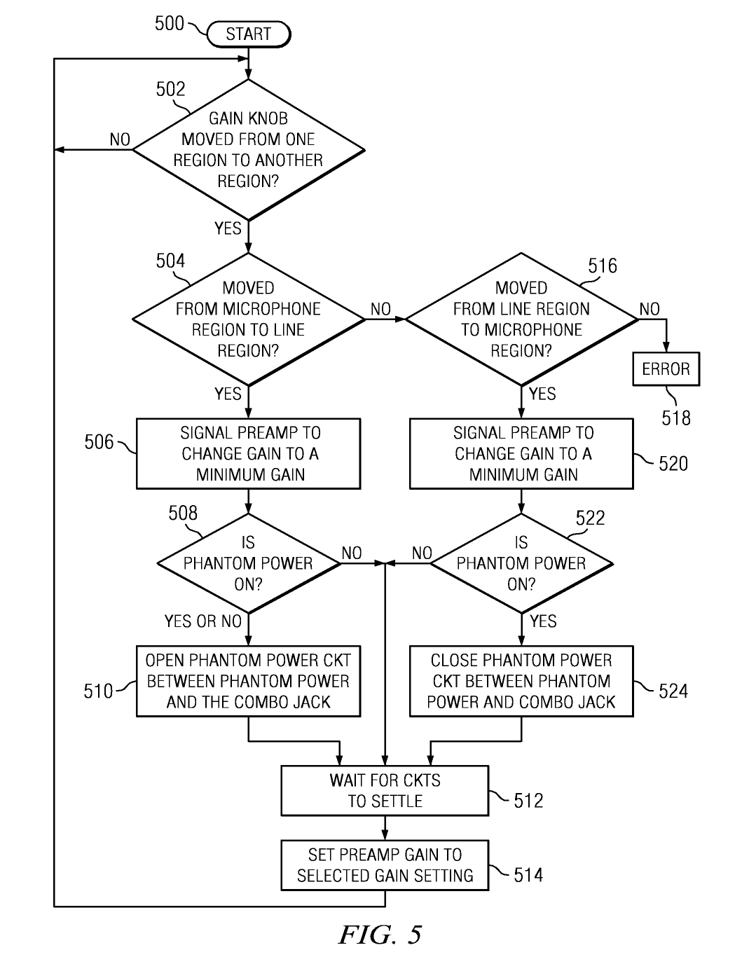

Referring now to FIG. 5, a flow chart is provided to describe how an embodiment of the invention switches, via microcontroller control, between microphone mode and line mode. Embodiments of the invention allow a user to switch from having a microphone connected to, for example, combo jack A 302, to having a line input plugged into combo jack A 302. If the microphone previously connected to the combo jack A 302 was a condenser microphone, which required phantom power, 48V DC, to be connected via line 332 to the combo jack A 302, and the user is desirous of changing form microphone mode to line mode, it becomes important that phantom power is not provided to a line plug placed in the combo jack 302 when operating in line mode.

Most audio equipment that provides a line output is not designed to receive 48 volts DC or for that matter any significant DC voltage as an input at its line output jack. Thus, embodiments of the invention are designed to provide some level of protection for such a situation. That is, referring to FIGS. 2, 3 and 5, when the gain control knob indicator 202 crosses the mode switch position or resistance position 203 from, for example, the microphone region 204 to the line region 206 a plurality of events occur, which help protect audio and amplifier circuitry from both an instantaneous change in gain settings that may cause loud unwanted audio cracks or booming sounds as well as damage to circuitry due to phantom power being placed on connection contacts of the combo jack input, which may now be connected to a line signal (rather than a microphone).

At step 500, the microcontroller is starting a function wherein the firmware instructs it to sense or monitor for a change in position of the gain-mode mechanism 308. If the gain-mode mechanism 308 is sensed as being moved, but is not moved from the microphone region 204 to the line region 206 or vis-à-vis, then only the gain of the programmable preamp 310 may be adjusted via gain instructions provided from the microcontroller 306. Conversely, if at step 502 the microcontroller 306 via the A/D converter 320 senses that the gain-mode potentiometer 308 has crossed a mode switch position 203 and moved from, for example, the microphone region 204 to the line region 206, then at step 504 the process is moved to step 506.

At step 506, the microcontroller 306 communicates with the programmable preamp 310 to decrease its gain to a minimum or zero gain such that the output A 312 is substantially low or off. At step 508, a determination is made by the microcontroller 306 as to whether the phantom power switch 330 is in an on or off position and/or whether the phantom power control circuit 324 is producing a phantom power output voltage that is connected via connection 332 to the combo jack A 302. If the phantom power is determined to be on, then at step 510 a relay or transistor switch 331 is opened between the output of the regulated phantom power and the phantom power line 332 such that phantom power is not connected or provided to any pins or connection points within the combo jack A 302. In some embodiments, at step 510, the phantom power control circuit 324 is also signaled via signal line 326 by the microcontroller 306 to turn off, to disable the phantom power voltage regulator within the phantom power control circuit or to go into a low power state.

Referring back to step 508, if it is determined that the phantom power is not on, then different embodiments of the invention may perform slightly differently. In some embodiments, if at step 508 it is determined that the phantom power is not on, then to be sure that phantom power is not connected to the combo jack 302, a relay switch or solid state switch 331 is opened via microcontroller control. In other embodiments of the invention, if at step 508 the phantom power is determined to be off, then no further action with respect to phantom power control may be required and the process can go to step 312 wherein the circuitry waits for the programmable amplifier circuit output to settle.

Whether the regulated phantom power is on or off in step 508, at step 512, the circuit, via microcontroller 306 control waits for a few microseconds to a number of seconds for the signals on all the circuits and in particular the programmable preamp 310 to settle. After the short wait period, the microcontroller 306 reads the output of the A/D converter 320, which is providing an indication of the user selected gain setting in the line region 206 of the gain-mode potentiometer/mechanism 308. The microcontroller 306 uses the indication of the gain-mode potentiometer/mechanism 308 setting to, via a lookup table in the memory 328, provide a gain setting instruction via data bus 322 to the programmable preamp 310. Although other gain setting may be made available in other embodiments, in line mode the programmable preamp can be set to one of the user selected line gain settings of either +4 dBu or +14 dBu. The microcontroller 306 also provides a signal, via connection 327, to set an appropriate amount of signal attenuation in the gain stage attenuator A 334. Setting the attenuation of the gain stage attenuator A 334 (if incorporated into an embodiment) generally occurs at about the same time or in sequence with setting the line gain of the programmable preamp 310. As such, embodiments of the invention disconnect phantom power voltage from a combo jack, turn off the regulated phantom power voltage, and/or place the phantom power control circuit into a low power state when the gain-mode potentiometer/knob 308 is moved from the microphone region 204 past a mode switch position 203 and into the line region 206 regardless of whether the associated phantom power switch is in an on or off position.

Returning to step 504, if it is determined that the gain knob has not been moved from the microphone region 204 to the line region 206, then at step 516 it is determined by the microcontroller 306 whether the gain-mode mechanism 308 has been moved from indicating or pointing to the line region 206, past a mode switch position 203 and into the microphone region 204. If the answer is no, then an error is produced at step 518. If the answer is yes, the gain-mode mechanism 308 has been moved from the line mode region 206 to the microphone mode region 204. At step 520, the microcontroller 306 provides a signal via bus 322 to the programmable preamp 310 that instructs the programmable preamp to change its gain to a minimum gain, 0 dB gain or zero output setting.

At step 522, it is then determined whether the phantom power control circuit A 324 is producing phantom power. The user may turn phantom power on via phantom power switch A 330 if a condenser microphone is to be connected to the combo jack A 302. Conversely, if a dynamic microphone is to be used with the combo jack A 302, a user may switch the phantom power off. Finally, if the combo jack was previously connected to a line input, a user may have switched the phantom power switch to the off position or may have forgotten to switch the phantom power off. Regardless of the position of the phantom power switch, at step 522, if the phantom power is not on, then at step 512 the microprocessor waits for a few microseconds while the programmable preamp and other related circuitry settles. If it is determined at step 522 that the phantom power switch is in the on position, meaning, in this case, that the phantom power switch A 330 is in the on position and the microcontroller 306 has read the position of the phantom power switch, then at step 524, the phantom power control circuit 324 is communicated with via signal line 326 such that the relay or solid state switch 331 between the output of the regulated phantom power and the combo jack A 302 is closed and, if the phantom power circuitry had been turned off, such circuitry is turned on such that the regulated phantom power is produced and provided to a pin or connection within the combo jack A 302.

At step 512, the microcontroller waits for a predetermined time period while the various circuits in the embodiment settle for a few microseconds. At step 514, the microcontroller reads the gain setting of the gain-mode mechanism 308 via the A/D converter 320. The microcontroller uses the gain setting indication from the A/D converter 320 to look up an appropriate gain setting instruction in a lookup table found in memory 328. The microcontroller 306 then provides the gain setting instruction via data line 322 to the programmable preamp 310. The programmable preamp 310 will then increase its gain to the instructed gain setting and provide an appropriate amplified signal output appropriately at output A 312.

In some embodiments, a second line-microphone input circuit B portion 316, which is substantially similar to the circuit A portion 314, is provided. This second circuit B portion 316 comprises phantom power control circuitry, gain stage attenuator circuitry (in some embodiments) and programmable preamp circuitry much like the line-microphone input circuitry 314. The circuit B portion 316 is connected to the data bus 322 and in turn to the microcontroller 306. The circuit B portion 316 further has phantom power control lines 326a and a gain stage attenuator line 327a each connected to the microcontroller 306 similarly as already described above for the circuit A portion 314. Combo jack B 304 is connected to the circuit B portion 316 such that phantom power line 332a is connected to the combo jack B 304 and either line input or microphone input audio signals are connected from combo jack B 304 via line 342a to the second circuitry 316. Output B 344 is the amplified output signal of either the line input or the microphone input provided at combo jack B 304 depending on whether the circuit B portion 316 is configured to be in line mode or microphone mode (with or without phantom power) and the audio signal is being input into combo jack B 304.

Referring back to FIG. 3, in some embodiments when in microphone mode and for one gain setting in line mode, the gain stage attenuator 334, is set to a unity gain such that there is no attenuation through or a straight signal feed through the gain stage attenuator 334 from the combo jack input 342 to the programmable preamp 310. Conversely, for some programmable preamps that may be successfully used in embodiments of the invention, when in line mode and receiving a line signal via the combo jack 302, the gain stage attenuator attenuates the line signal delivered via connection 342 to a usable and acceptable programmable preamp input level prior to sending the line signal to the programmable preamp 310. Thus, in some embodiments, the total gain achieved at output A 312 is a combination of the attenuation of the gain stage attenuator 334 and the amplification of the attenuated signal via the programmable preamp 310.

The microcontroller 306 is connected to the gain stage attenuator 334 via gain stage signal line 327. The microcontroller 306, depending on the mode setting of the gain-mode potentiometer 308, instructs the gain stage attenuator either to attenuate the received line signal by a predetermined dB amount or to provide a unity gain to the signal (or to pass the line signal straight through the gain stage attenuator) and then output the attenuated or substantially unchanged line signal to the programmable preamp 310. Furthermore, when the gain-mode potentiometer 308 is set to or positioned in the line region 206 such that the embodiment is operating in line mode, the microcontroller reads the gain setting of the gain gain-mode potentiometer 308 as being either +4 dBu or +14 dBu and signals the gain stage attenuator 334 via connection 327 to apply an appropriate level of attenuation to the line signal. In other embodiments or potential variations of the invention, the appropriate level of attenuation may be zero attenuation when the gain-mode potentiometer 308 is set at +4 dBu and be a higher level of attenuation when the gain-mode potentiometer 308 is set at +14 dBu.

Thus, it is understood that an advantage of various embodiments of the invention is that the phantom power output and/or the phantom power connection to a combo output jack is dynamically controlled based on the embodiments selected mode of operation (i.e., microphone mode or line mode), which is inherently related to the gain setting of the gain-mode knob 308. In other words, embodiments of the invention determine whether to operate in line mode and disconnect phantom power from an input jack regardless of whether a user set phantom power switch is in an on position, or to operate in microphone mode and allow phantom power to connect to the an input jack when a phantom power switch is in an on position depending on a gain setting position of a user adjustable gain-mode potentiometer/knob. Thus, when a user adjusts the gain-mode potentiometer/knob to a gain setting that is inherently used for line inputs, regardless of whether phantom power was previously being provided to the input jack, embodiments of the invention will remove phantom power from being provided to the input jack. Embodiments of the present invention help to eliminate costly mistakes made by a user wherein the phantom power switch is turned on and a prior art device allows the 48 volt DC phantom power to be provided to the input jack of the device while a line input is connected to the jack. Embodiments of the present invention may be considered by some to be more useful when a combo jack is being used on audio device to provide an input for various types of microphones or acoustic pickup devices having either an XLR connector or a quarter inch standard audio plug connector as well as to provide an input for an audio line signal input having a quarter inch standard audio plug connector.

It will be appreciated by those skilled in the art having the benefit of this disclosure that the herein described exemplary combination line or microphone input circuitry provides dynamic control over whether phantom power is provided to a combo jack based on a user selected audio signal gain setting. It should be understood that the drawings and detailed description herein are to be regarded in an illustrative rather than a restrictive manner, and are not intended to be limiting to the particular forms and examples disclosed. On the contrary, included, discussed, and inherently referred to herein are many further modifications, changes, rearrangements, substitutions, alternatives, design choices, and embodiments that are apparent to those of ordinary skill in the art, without departing from the principles and scope hereof, as defined by the following claims. Thus, it is intended that the following claims be interpreted to embrace all such further modifications, changes, rearrangements, substitutions, alternatives, design choices, and embodiments.

What is claimed is:

1. A combination line or microphone input circuit comprising:
a microcontroller adapted to perform predetermined instructions;
an input connection for receiving a line input signal or a microphone input signal, the input connection comprising a plurality of connection pins;
a user adjustable mechanism configured to provide a user settable line mode gain indication within a line mode gain range or a user settable microphone mode gain indication within a microphone mode gain range, the user adjustable mechanism being electrically monitored by the microcontroller; and
a programmable preamp circuit in communication with the microcontroller, the programmable preamp being connected to the input connection, the programmable preamp configured to adjust the programmable preamp circuit gain in response to receipt of microphone mode gain setting instructions communicated from the microcontroller when the microcontroller monitors the user adjustable mechanism as being set within the microphone mode gain range, the programmable preamp being further configured to adjust the programmable preamp circuit gain in response to receipt of line mode gain setting instructions communicated from the microcontroller when the microcontroller monitors the user adjustable mechanism as being set within the line mode gain range.

2. The combination line or microphone input circuit of claim 1, further comprising:
a phantom power switch having an on position and an off position, the on position and the off position being user selectable;
a phantom power control circuit adapted to power-down a regulated phantom power circuit in response to receipt of a phantom-power-off signal provided by the microcontroller when the microcontroller monitors the user adjustable mechanism as being set within the line mode gain range, the phantom power control circuit further adapted power-up the regulated phantom power circuit in response to receipt of a phantom-power-on signal provided by the microcontroller when the microcontroller monitors that both the user adjustable mechanism is set within the microphone mode gain range and the phantom power switch is in the on position, the regulated phantom power circuit having a phantom voltage output adapted to be connected to at least one of the plurality of connection pins.

3. The combination line or microphone input circuit of claim 1, further comprising an analog to digital (A/D) converter circuit connected to both the user adjustable mechanism and to the microcontroller, the A/D converter adapted to provide a digital indication of the user adjustable mechanism's setting to the microcontroller.

4. The combination line or microphone input circuit of claim 1, wherein the input connection is a combo jack adapted to accept at least two different types of plugs.

5. The combination line or microphone input circuit of claim 1, wherein the line mode gain setting instructions comprise a first gain setting instruction associated with a first portion of the line mode gain range and a second gain setting instruction associated with a second portion of the line mode gain range.

6. The combination line or microphone input circuit of claim 5, wherein the first portion of the line mode gain range and the second portion of the line mode gain range substantially comprise the entire line mode gain range.

7. The combination line or microphone input circuit of claim 1, further comprising a non-volatile memory being in communication with the microcontroller, the non-volatile memory comprising the predetermined instructions and a look-up table of line mode gain setting instructions and microphone mode gain setting instructions.

8. The combination line or microphone input circuit of claim 1, wherein the user adjustable mechanism is selected from the group consisting of a potentiometer, a resistive slider, a digital position sensor, and a shaft encoder.

9. The combination line or microphone input circuit of claim 1, further comprising at least one mode switch position on the user adjustable mechanism, the mode switch position being a location between the line mode gain range and the microphone mode gain range, the programmable preamp being adapted to adjust the programmable preamp circuit gain to substantially zero in response to receipt of a zero gain setting instruction communicated from the microcontroller when the microcontroller monitors the user adjustable mechanism as indicating the at least one mode switch position.

10. A combination line or microphone input circuit comprising:
an input connection adapted to receive a line input signal or a microphone input signal, the input connection comprising a plurality of connection contacts;
an adjustable mechanism comprising gain indication settings for line mode gain settings and gain indication settings within a microphone mode gain range;
a programmable preamp circuit electrically connected to receive the line input signal or the microphone input signal from the input connection;
a phantom power switch having an on position and an off position;
a phantom power control circuit comprising a phantom power regulated voltage circuit adapted to produce a phantom power voltage output;
a microcontroller electrically connected to the adjustable mechanism, the programmable preamp, the phantom power switch, and the phantom power control circuit; and
a memory electronically coupled to the microcontroller;
a plurality of instructions wherein at least a portion of the plurality of instructions are storable in the memory, and further wherein the plurality of instructions are configured to cause the microcontroller to perform:
monitoring the gain indication setting of the adjustable mechanism;
determining whether the gain indication setting changes from being within microphone mode gain range to being within the line mode gain settings;
providing a minimum gain preamp instruction to the programmable preamp circuit that instructs the programmable preamp to set a gain to a minimum if the gain indication setting is changed from being within the microphone mode gain range to being within the line mode gain settings;
determining if the phantom power regulated voltage circuit is on;
providing a phantom power signal, to the phantom power control circuit, disabling the phantom power voltage output from being provided to a connection contact of the input connection if the phantom power regulated voltage circuit is on; and
providing a line mode amplification instruction to the programmable preamp, the line mode amplification instruction adapted to instruct the programmable preamp to set the gain to one of a plurality of distinct line mode gain settings.

11. The combination line or microphone input circuit of claim 110, wherein disabling the phantom power voltage output from being provided the connection contact of the input connection further comprises effectively opening an electrical connection between the phantom power voltage output and the connection contact.

12. The combination line or microphone input circuit of claim 10, wherein the plurality of instructions are further configured to cause the microcontroller to perform:
determining if the gain indication setting is within the microphone mode gain range;
determining if the phantom power switch is in the off position;
determining whether the phantom power switch is switched between the on position and the off position;
providing the minimum gain preamp instruction to the programmable preamp circuit instructing the programmable preamp to set the gain to a minimum if the phantom power switch is switched between the on position and the off position;
providing a phantom power on instruction to the phantom power control circuit if the phantom power switch was switched from the off position to the on position;
providing a phantom power off instruction to the phantom power control circuit if the phantom power switch was switched from the on position to the off position;
determining the gain indication setting;
providing a microphone mode amplification instruction to the programmable preamp that instructs the programmable preamp to set a gain associated with the gain indication setting.

13. The combination line or microphone input circuit of claim 10, wherein the plurality of instructions are further configured to cause the microcontroller to perform:
determining whether the gain indication setting changes from being within line mode gain settings to being within the microphone mode gain range;
providing a minimum gain preamp instruction to the programmable preamp circuit that instructs the programmable preamp to set a gain to a minimum if the resistance setting changed from being within the line mode gain settings to being within the microphone mode gain range;
determining if the phantom power switch is in the on position or in the off position;
signaling the phantom power control circuit and thereby activating the phantom power voltage circuit to produce the phantom power voltage output if the phantom power switch is in the on position;
signaling the phantom power control circuit and thereby deactivating the phantom power voltage circuit from producing the phantom power voltage output if the phantom power switch is in the off position.

14. The combination line or microphone input circuit of claim 13, wherein signaling the phantom power control circuit if the phantom power switch is in the on position further comprises effectively closing an electrical connection between the phantom power voltage output and the connection contact.

15. The combination line or microphone input circuit of claim 13, wherein signaling the phantom power control circuit if the phantom power switch is in the off position further comprises effectively opening an electrical connection between the phantom power voltage output and the connection contact.

16. The combination line or microphone input circuit of claim 10, further comprising a gain stage attenuator connected between the input connection and the programmable preamp circuit.

17. An audio device comprising:
an input connection adapted to receive a line input signal or a microphone input signal, the input connection comprising a plurality of connection contacts;
an adjustable mechanism comprising gain indication settings within a line mode range and gain indication settings within a microphone mode range;
a programmable preamp circuit adapted to amplify a received signal in accordance with a gain instruction, the programmable preamp electrically connected to receive the line input signal or the microphone input signal from at least a first contact of the input connection, the programmable preamp comprising a preamp signal output adapted for connection to other circuitry in the audio device;
a microcontroller electrically connected to the adjustable resistor, the programmable preamp, and
a memory electronically coupled to the microcontroller;
a plurality of instructions wherein at least a portion of the plurality of instructions are storable in the memory, and further wherein the plurality of instructions are configured to cause the microcontroller to perform:
monitoring the gain indication setting of the adjustable mechanism;
determining whether the gain indication setting changes from being within the microphone mode range to being within the line mode range;
providing a minimum preamp gain instruction to the programmable preamp circuit instructing the programmable preamp to amplify a received signal with a zero or minimum gain if the gain indication setting changes from being within the microphone mode range to being within the line mode range; and
providing a line mode gain instruction to the programmable preamp that is adapted to instruct the programmable preamp to set the gain to one of a plurality of distinct line mode gain settings.

18. The audio device of claim 17, further comprising:
a phantom power switch having an on position and an off position;
a phantom power control circuit comprising a phantom power voltage circuit adapted to produce a phantom power voltage output;
wherein the microcontroller is further electrically connected to the phantom power switch, and the phantom power control circuit; and
wherein the plurality of instructions are further configured to cause the microcontroller to perform the step of providing a phantom power signal, to the phantom power control circuit, the phantom power signal being adapted to disable the phantom power voltage circuit from providing an output to a second connection contact of the input connection if the phantom power regulated voltage circuit is on.

19. The audio device of claim 17, wherein the plurality of distinct line mode gain settings comprise +4 dBu and +14 dBu.

20. The audio device of claim 17, wherein the plurality of instructions are further configured to cause the microcontroller to perform:
determining if the gain indication setting is within the microphone range;
determining whether the phantom power switch is switched between the on position and the off position;
providing a minimum preamp gain instruction to the programmable preamp circuit instructing the programmable preamp circuit to amplify a received signal with a zero or minimum gain if the phantom power switch is switched between the on position and the off position;
providing a phantom power on instruction to the phantom power control circuit if the phantom power switch was switched from the off position to the on position;
providing a phantom power off instruction to the phantom power control circuit if the phantom power switch was switched from the on position to the off position;
determining the gain indication setting;
providing a microphone mode gain instruction to the programmable preamp circuit instructing the programmable preamp circuit to amplify the received signal with a gain associated with the determined gain indication setting.

21. The combination line or microphone input circuit of claim 1, further comprising a gain stage attenuator circuit connected between the input connection and the programmable preamp circuit, the gain stage attenuator configured to receive a pass/attenuate signal from the microcontroller; if a pass signal is received by the gain stage attenuator circuit then the gain stage attenuator is configured to pass the line input signal or the microphone input signal with minimal attenuation before provided the line input signal or the microphone input signal to the programmable preamp circuit, and if an attenuate signal is received by the gain stage attenuator circuit, then the gain stage attenuation circuit is configured to attenuate the line input signal or the microphone input signal before providing the line input signal or the microphone input signal to the programmable preamp circuit.
